(19) United States
(12) Patent Application Publication
(10) Pub. No.: US 2023/0005782 A1
(43) Pub. Date: Jan. 5, 2023

(54) FILM-LIKE ADHESIVE AND METHOD FOR EVALUATING EASE OF SPLITTING, DICING/DIE-BONDING INTEGRATED FILM AND METHOD FOR MANUFACTURING, AND SEMICONDUCTOR DEVICE

(71) Applicant: Showa Denko Materials Co., Ltd., Chiyoda-ku, Tokyo (JP)

(72) Inventors: Daisuke YAMANAKA, Chiyoda-ku, Tokyo (JP); Michiko KAYA, Chiyoda-ku, Tokyo (JP)

(21) Appl. No.: 17/771,020

(22) PCT Filed: Mar. 25, 2020
(86) PCT No.: PCT/JP2020/013478

§ 371 Date: Apr. 22, 2022

(30) Foreign Application Priority Data
Oct. 28, 2019 (JP) 2019-195277

(51) Int. Cl. H01L 21/683

(52) U.S. Cl. CPC H01L 21/6836

(57) ABSTRACT

A method for evaluating an ease of splitting of a film-like adhesive under low-temperature conditions in which cooling expansion is performed, the method including: preparing a sample having a cross-sectional area A (mm²) from a film-like adhesive; determining a breaking work W (N·mm), a breaking strength P (N), and a breaking elongation L (mm) of the sample by a break test under low-temperature conditions in a range of −15° C. to 0° C.; determining a breaking factor m of the sample expressed by Equation (1) below; and determining a breaking resistance R (N/mm²) of the sample expressed by Equation (2) below; and evaluating the ease of splitting based on the determined the breaking factor m and the breaking resistance R,

m=W/[1000×(P×L)] (1)

R=P/A (2).

### TECHNICAL FIELD

The present disclosure relates to a film-like adhesive, a method for evaluating the ease of splitting of the film-like adhesive, a dicing/die-bonding integrated film, a method for manufacturing the dicing/die-bonding integrated film, and a semiconductor device.

### BACKGROUND ART

A semiconductor device such as IC is manufactured, for example, through the following steps. First, a semiconductor wafer is pasted to an adhesive sheet for dicing, and in this state, the semiconductor wafer is singulated into semiconductor chips (dicing step). Thereafter, a pickup step, a pressure bonding step, a die bonding step, and the like are performed. Patent Literature 1 discloses a dicing/die-bonding film having both a function of fixing a semiconductor wafer in a dicing step and a function of bonding a semiconductor chip to a substrate in a die bonding step. In the dicing step, the semiconductor wafer and the die-bonding film (film-like adhesive) are singulated to obtain adhesive piece-attached chips.

Conventionally, dicing of a semiconductor wafer and a bonding adhesive layer has been performed by physical cutting using a blade or the like. In recent years, a decrease in thickness of a wafer has been developed in accordance with higher integration of a semiconductor package. Due to this, defects such as chip cracking during the dicing step are likely to occur. In the dicing step using a wafer having a thickness of 50 μm or less as a target, from the viewpoint of maintaining a high yield, new processing methods alternative to conventional physical cutting methods have been developed.

As one of the new processing methods, a method has been known in which a predetermined cutting line is formed on an object to be processed by laser and the object to be processed is then split along the predetermined cutting line (see Patent Literatures 2 and 3). The process of singulating a wafer by this method is referred to as stealth dicing. In Patent Literatures 4 and 5, the mechanical characteristics or the thermal characteristics of a dicing film (adhesive layer) to be applied to stealth dicing have been studied.

### CITATION LIST

### Patent Literature

Patent Literature 1: Japanese Unexamined Patent Publication No. 2008-218571
Patent Literature 2: Japanese Unexamined Patent Publication No. 2002-192370
Patent Literature 3: Japanese Unexamined Patent Publication No. 2003-338467
Patent Literature 4: Japanese Unexamined Patent Publication No. 2015-211080
Patent Literature 5: Japanese Unexamined Patent Publication No. 2016-115775

### SUMMARY OF INVENTION

### Technical Problem

Regarding the dicing film to be applied to stealth dicing, the applicability of the dicing film to stealth dicing can be estimated to some extent by evaluating the mechanical characteristics or the thermal characteristics thereof (see Patent Literatures 4 and 5). On the other hand, according to the studies of the present inventors, regarding a die-bonding film (film-like adhesive), a variation in measurement values regarding the mechanical characteristics or the thermal characteristics thereof is large, and thus it is difficult to evaluate the applicability of the die-bonding film to stealth dicing. Furthermore, the direction of improvement of the film-like adhesive cannot also be guided. For example, even if the breaking strength of the film-like adhesive is measured by a tensile test, a breaking point varies due to strain or the like at the time of attachment of a sample, and thus the measurement value is not stable. Furthermore, when a thickness increasing process is performed by laminating a plurality of film-like adhesives to prepare a sample, it takes a lot of trouble with this preparation, and the quality of the sample affects the measurement value. Thus, the ease of splitting of the film-like adhesive cannot be accurately evaluated.

The present disclosure provides a method by which the ease of splitting of a film-like adhesive under low-temperature conditions in which cooling expansion is performed can be evaluated with ease and excellent reproducibility. Furthermore, the present disclosure also provides a film-like adhesive that is satisfactorily split by cooling expansion, a dicing/die-bonding integrated film including the film-like adhesive as a bonding adhesive layer, a method for manufacturing the dicing/die-bonding integrated film, and a semiconductor device.

### Solution to Problem

An aspect of the present disclosure is a method for evaluating the ease of splitting of a film-like adhesive under low-temperature conditions in which cooling expansion is performed. This method for evaluating the ease of splitting includes: preparing a sample having a cross-sectional area A (mm²) from the film-like adhesive; determining a breaking work W (N·mm), a breaking strength P (N), and a breaking elongation L (mm) of the sample by a break test under low-temperature conditions in a range of −15° C. to 0° C.; determining a breaking factor in expressed by Equation (1) below; and determining a breaking resistance R (N/mm²) expressed by Equation (2) below.

m=W/[1000×(P×L)] (1)

R=P/A (2)

According to the studies of the present inventors, the breaking factor in and the breaking resistance R can be obtained by the break test (transverse rupture strength test) that is a relatively simple method under low-temperature conditions (−15° C. to 0° C.), and the reproducibility of results of the break test is high. Therefore, even if the ease of splitting of a plurality of film-like adhesives whose ease of splitting is to be evaluated is not actually evaluated, the ease of splitting of a film-like adhesive can be evaluated only by acquiring data of the breaking factor in and the breaking resistance R.

Another aspect of the present disclosure relates to a method for manufacturing a dicing/die-bonding integrated film including a base layer, an adhesive layer having a first surface facing the base layer and a second surface opposite to the first surface, and a bonding adhesive layer provided on the second surface of the adhesive layer. This manufacturing method includes: preparing a dicing film that is a laminate including a base layer and an adhesive layer; selecting a film-like adhesive having a breaking factor in of more than 0 and 70 or less and a breaking resistance R of more than 0 N/mm² and 40 N/mm² or less in the above-described method for evaluating of the ease of splitting that is performed under the following conditions; and forming a bonding adhesive layer formed from the film-like adhesive on a surface of the dicing film on the adhesive layer side.

<Conditions>

Sample width: 5 mm

Sample length: 23 mm

Relative speed between push jig and sample: 10 mm/min

According to the above-described manufacturing method, since the film-like adhesive having satisfactory ease of splitting under low-temperature conditions is used as the bonding adhesive layer, a dicing/die-bonding integrated film suitable for stealth dicing call be obtained.

Still another aspect of the present disclosure relates to a film-like adhesive to be applied to a manufacturing process of a semiconductor device in which cooling expansion is performed. This film-like adhesive has a breaking factor in of more than 0 and 70 or less and a breaking resistance R of more than 0 N/mm² and 40 N/mm² or less in the above-described method for evaluating of the ease of splitting that is performed under the following conditions.

<Conditions>

Sample width: 5 mm

Sample length: 23 mm

Relative speed between push jig and sample: 10 mm/min

Still another aspect of the present disclosure relates to a dicing/die-bonding integrated film. That is, this dicing/die-bonding integrated film includes: a base layer; an adhesive layer having a first surface facing the base layer and a second surface opposite to the first surface; and a bonding adhesive layer provided on the second surface of the adhesive layer, and the bonding adhesive layer is formed from the above-described film-like adhesive. Still another aspect of the present disclosure is a semiconductor device including the above-described film-like adhesive.

### Advantageous Effects of Invention

According to the present disclosure, there is provided a method by which the ease of splitting of a film-like adhesive under low-temperature conditions in which cooling expansion is performed can be evaluated with ease and excellent reproducibility. Furthermore, according to the present disclosure, there are also provided a film-like adhesive that is satisfactorily split by cooling expansion, a dicing/die-bonding integrated film including the film-like adhesive as a bonding adhesive layer, a method for manufacturing the dicing/die-bonding integrated film, and a semiconductor device.

### BRIEF DESCRIPTION OF DRAWINGS

FIG. 1A is a plan view schematically illustrating an embodiment of a dicing/die-bonding integrated film according to the present disclosure, and FIG. 1B is a schematic cross-sectional view taken along line B-B of FIG. 1A.

FIG. 2A and FIG. 2B are cross-sectional views schematically illustrating a process of manufacturing adhesive piece-attached chips.

FIG. 3A and FIG. 3B are cross-sectional views schematically illustrating the process of manufacturing adhesive piece-attached chips.

FIG. 4 is a perspective view schematically illustrating a sample in a state of being fixed to a jig.

FIG. 5 is a cross-sectional view schematically illustrating a state where a load is applied to the sample by a push jig.

FIG. 6 is a graph schematically showing an example of results of a break test.

FIG. 7 is a graph on which results of Examples and Comparative Examples are plotted.

FIG. 8 is a graph on which results of a break test performed eight times in each of Example 4 and Comparative Example 4 are plotted.

FIG. 9 is a graph showing results of a tensile test performed three times for a sample of a film-like adhesive under low-temperature conditions.

### DESCRIPTION OF EMBODIMENTS

Hereinafter, embodiments of the present disclosure will be specifically described with reference to the drawings. However, the present invention is not limited to the following embodiments. Note that, in the present specification, “(meth)acrylic acid” means acrylic acid or methacrylic acid, and “(meth)acrylate” means acrylate or methacrylate corresponding thereto. The expression “A or B” means that either one of A and B may be contained or both of A and B may be contained.

In the present specification, the term “layer” encompasses a structure of a shape thereof formed all over a surface seen as a plan view and also a structure of a shape thereof partially formed. Furthermore, in the present specification, the term “step” includes not only an independent step, and even if one step cannot be clearly distinguished from other steps, such step is included in the “step” as long as effects intended to be exerted by this step is attained. Furthermore, a numerical range expressed by using “to” indicates a range including the numerical values before and after “to” as the minimum value and the maximum value, respectively.

In the present specification, in a case where a plurality of substances corresponding to each component exist in a composition, a content of each component in the composition means the total amount of the plurality of substances that exist in the composition, unless otherwise specified. Furthermore, unless otherwise specified, exemplified materials may be used alone or may be used in combination of two or more kinds thereof. Furthermore, in a numerical range described in stage in the present specification, an upper or lower limit value of a numerical range of one stage may be replaced with an upper of lower limit value a numerical range in another stage. Furthermore, in a numerical range described in the present specification, an upper or lower limit value of the numerical range may be replaced with a value shown in Examples.

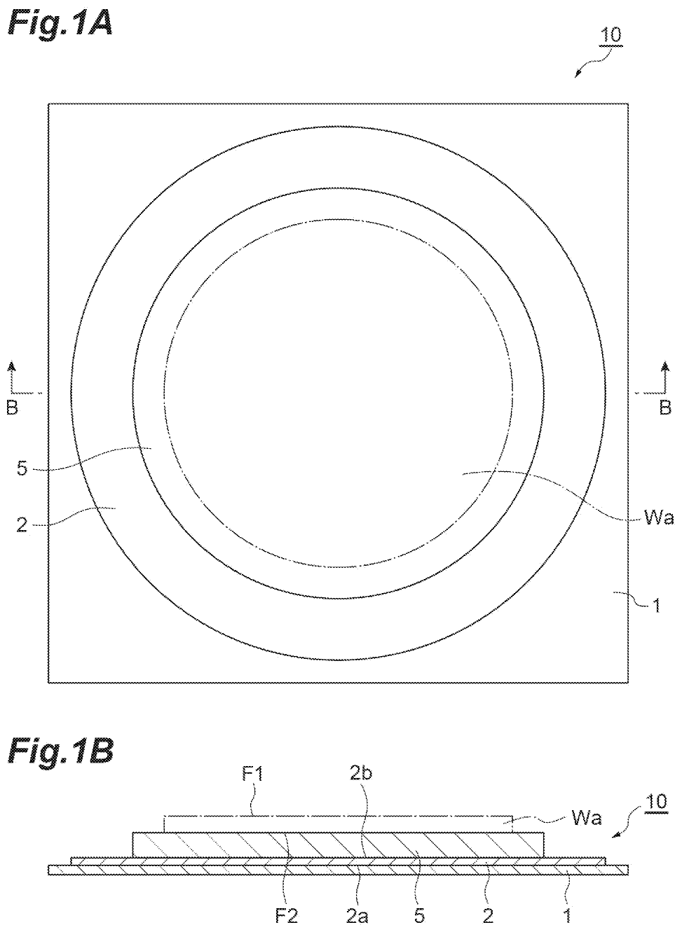

A film-like adhesive according to the present embodiment is to be pasted to a surface F2 of a semiconductor wafer Wa on a side opposite to a circuit surface F1 in a manufacturing process of a semiconductor device (see FIG. 1A and FIG. 1B). Herein, a dicing/die-bonding integrated film including a bonding adhesive layer formed from a film-like adhesive will be described.

FIG. 1A is a plan view illustrating a dicing/die-bonding integrated film of the present embodiment, and FIG. 1B is a schematic cross-sectional view taken along line B-B of FIG. 1A. A dicing/die bonding integrated film 10 (hereinafter, simply referred to as the “film 10” in some cases) includes: a base layer 1; an adhesive layer 2 having a first surface 2a facing the base layer 1 and a second surface 2b opposite to the first surface 2a; and a bonding adhesive layer 5 provided to cover a center portion of the second surface 2b of the adhesive layer 2, in this order. The film 10 is applied to the manufacturing process of a semiconductor device, the process including: forming a predetermined cutting line on the semiconductor wafer Wa by laser; singulating the semiconductor wafer Wa and the bonding adhesive layer 5 by cooling expansion thereafter; and picking up adhesive piece-attached chips formed by the singulating step.

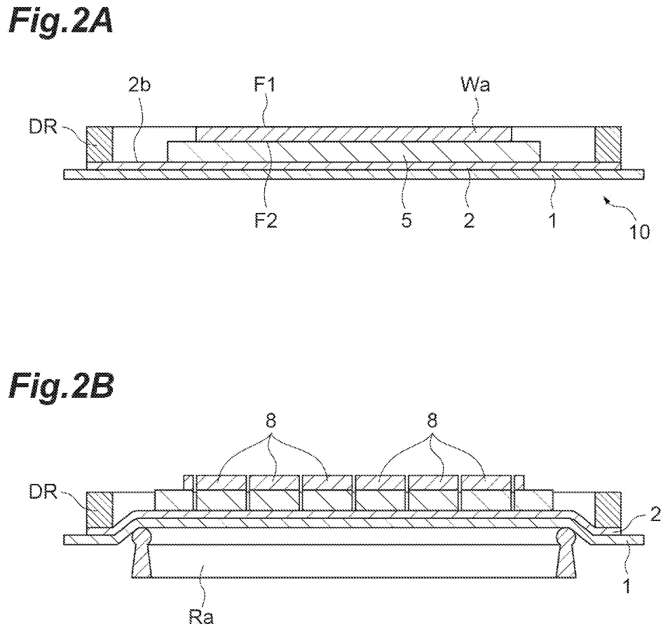

An example of a method for producing adhesive piece-attached chips 8 will be described. First, a protective film 20 is pasted to the circuit surface F1 of the semiconductor wafer Wa. The semiconductor wafer Wa is irradiated with laser to form a plurality of predetermined cutting lines (stealth dicing). Thereafter, the semiconductor wafer Wa is subjected to backgrinding and polishing treatment. Next, as illustrated in FIG. 2A, the film 10 is pasted so that the bonding adhesive layer 5 is in contact with the surface F2 of the semiconductor wafer Wa. Furthermore, a dicing ring DR is pasted to the second surface 2b of the adhesive layer 2. Thereafter, the semiconductor wafer Wa and the bonding adhesive layer 5 are singulated by cooling expansion under a temperature condition of −15° C. to 0° C. As illustrated in FIG. 2B, an inner region 1a of the dicing ring DR in the base layer 1 is thrust by a ring Ra so as to impart tension to the base layer 1. Thereby, the semiconductor wafer Wa is split along the predetermined cutting line, the bonding adhesive layer 5 is also split according to this, and a plurality of adhesive piece-attached chips 8 are obtained on the surface of the adhesive layer 2.

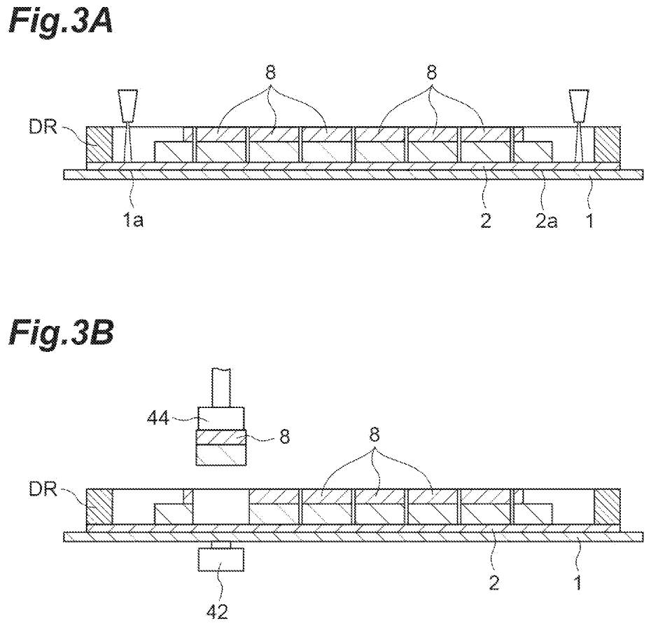

The inner region 1a of the dicing ring DR in the base layer 1 is heated so as to contract the inner region 1a. FIG. 3A is a cross-sectional view schematically illustrating a state where the inner region 1a is heated by blow of a heater H. The inner region 1a is contracted into a ring shape to impart tension to the base layer 1. As a result, a gap between adjacent adhesive piece-attached chips 8 can be widened. Thereby, occurrence of pickup errors can be further suppressed, and the visibility of the adhesive piece-attached chips 8 in the pickup step can be improved. After the adhesive force of the adhesive layer 2 is lowered by ultraviolet irradiation as necessary, as illustrated in FIG. 3B, the adhesive piece-attached chip 8 is thrust by a thrusting jig 42 to peel the adhesive piece-attached chip 8 off from the adhesive layer 2, and the adhesive piece-attached chip 8 is picked up by suction with a suction collet 44. The picked-up adhesive piece-attached chips 8 are conveyed to an assembly device (not illustrated) of the semiconductor device and pressure-bonded to a circuit board or the like.

The bonding adhesive layer 5 provided in the film 10 has a breaking factor in of more than 0 and 70 or less and a breaking resistance R of more than 0 N/mm² and 40 N/mm² or less in the method for evaluating the ease of splitting which uses results of a break test that is performed under the following conditions.

<Conditions>

Sample width: 5 mm

Sample length: 23 mm

Relative speed between a push jig and a sample: 10 mm/min

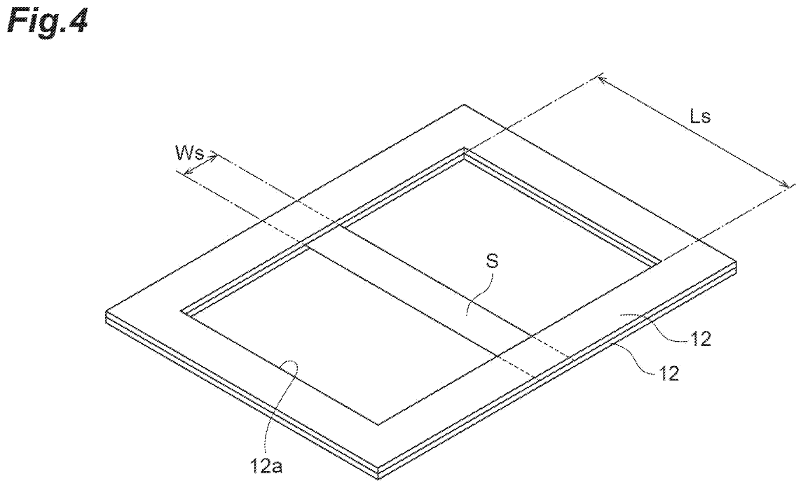

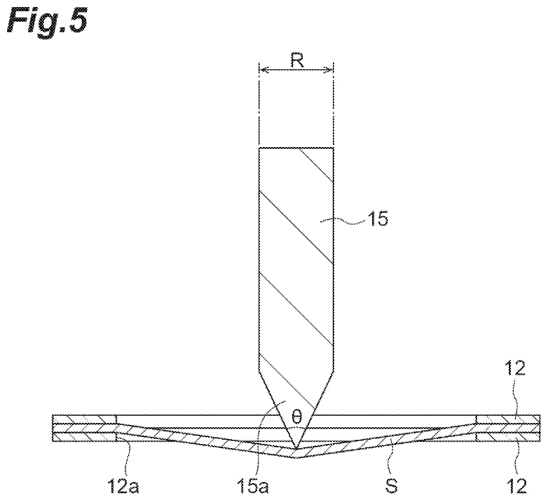

Hereinafter, the break test will be described. The break test is classified as the transverse rupture strength test and includes a step of pushing the center portion of the sample until the sample is broken in a state where both ends of the sample are fixed. As shown in FIG. 4, a sample S is provided to a break test in a state where the sample is fixed by being sandwiched between a pair of jigs 12 and 12. The pair of jigs 12 and 12 is formed from, for example, thick paper having a sufficient strength and each has a rectangular opening 12a at the center. A load is applied to the center portion of the sample S in a fixed state by a push jig 15 (see FIG. 5).

The sample S may be obtained by cutting the film-like adhesive as an evaluation target, and it is not necessary to produce a sample by stacking a plurality of adhesive pieces cut from the film-like adhesive. That is, the thickness of the sample S may be the same as the thickness of the film-like adhesive. The width (Ws in FIG. 4) of the sample S is, for example, 1 to 30 mm and may be 3 to 8 mm. The width thereof may be set to an appropriate width according to the status of a measurement device. The length (Ls in FIG. 3) of the sample S is, for example, 5 to 50 mm and may be 10 to 30 mm or 6 to 9 mm. The length of the sample S depends on the size of the opening 12a of the jig 12. Note that, the shape of the jig 12 and the size of the sample S may be other than those described above as long as a break test can be performed.

The push jig 15 is formed from a cylindrical member having a conical tip portion 15a. The diameter (R in FIG. 5) of the push jig 15 is, for example, 3 to 15 mm and may be 5 to 10 mm. The angle (θ in FIG. 5) of the tip portion 15a is, for example, 40 to 120° and may be 60 to 100°.

The break test is performed in a thermostat bath set at a predetermined temperature. The thermostat bath may be set to a constant temperature in a range of −15° C. to 0° C. (temperature of cooling expansion to be assumed). As the thermostat bath, for example, TLF-R3-F-W-PL-S manufactured by AETEC Co., Ltd. can be used. The breaking work W, the breaking strength P, and the breaking elongation L are obtained using an autograph (for example, AZT-CA01 manufactured by A&D Company, Limited, load cell 50 N, compression mode).

The relative speed between the push jig 15 and the sample S is, for example, 1 to 100 mm/min and may be 5 to 20 mm/min. When this relative speed is too fast, there is a tendency that data of breaking process cannot be sufficiently acquired, and when the relative speed is too slow, there is a tendency that stress is alleviated and thus breaking is not enough. The pushing distance of the jig 15 is, for example, 1 to 50 mm and may be 5 to 30 mm. When the pushing distance is too short, there is a tendency that breaking is not enough. Regarding the film-like adhesive as an evaluation target, it is preferable that a plurality of samples are prepared, the break test is performed plural times, and then the stability of test results is checked.

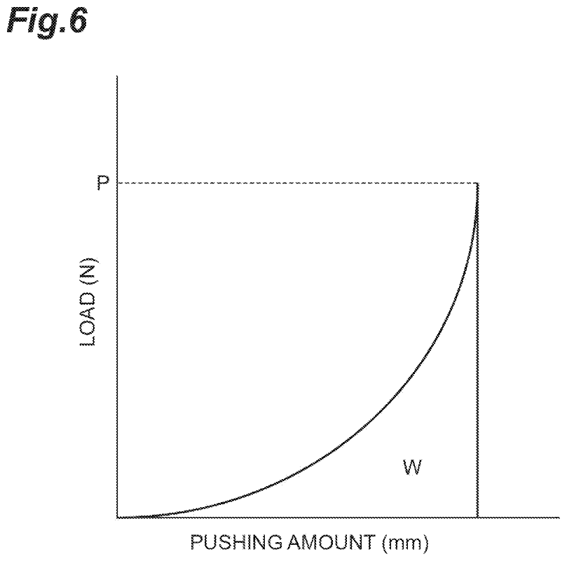

FIG. 6 is a graph showing an example of results of a break test. As shown in FIG. 6, the breaking work W is a surrounded area when the graph is created while the vertical axis represents a load and the horizontal axis represents a pushing amount until the sample S is broken. The breaking strength P is a load when the sample S is broken. The breaking elongation L is an elongation amount of the sample S when the sample S is broken. The breaking elongation L may be calculated using a trigonometric function from the pushing distance when the sample S is broken and the width of the opening 12a of the jig 12.

The breaking factor in (non-dimensional) and the breaking resistance R (N/mm²) are determined by Equation (1) and Equation (2) from values of the breaking work W (N·mm), the breaking strength P (N), and the breaking elongation L (mm) obtained by the break test.

m=W/[1000×(P×L)] (1)

R=P/A (2)

According to the studies of the present inventors, when the break test is performed under the following conditions, a film-like adhesive having a breaking factor in of more than 0 and 70 or less and a breaking resistance R of more than 0 N/mm² and 40 N/mm² or less has excellent ease of splitting actually at the time of cooling expansion in stealth dicing.

<Conditions>

Sample width: 5 mm

Sample length: 23 mm

Relative speed between the push jig and the sample: 10 mm/min

The breaking factor in (non-dimensional) is, as described above, more than 0 and 70 or less, preferably 10 to 60, and more preferably 15 to 55. The breaking factor in is a parameter regarding the stretching property of the film-like adhesive under low-temperature conditions. When the breaking factor in exceeds 70, the ease of splitting is insufficient due to excessive stretching property of the film-like adhesive. Note that, when the breaking factor in is 15 or more, the propagation of stress becomes satisfactory. The breaking resistance R is, as described above, more than 0 N/mm² and 40 N/mm² or less, preferably more than 0 N/mm² and 35 N/mm² or less, and more preferably 1 to 30 N/mm². When the breaking resistance R exceeds 40 N/mm², the ease of splitting is insufficient due to excessive strength of the film-like adhesive. Note that, when the breaking resistance R is 20 N/mm² or more, further superior ease of splitting is achieved by satisfactory stress propagation in low-temperature expansion. By selecting a film-like adhesive having a breaking factor in and a breaking resistance R in the above ranges as the film-like adhesive, stealth dicing can be satisfactorily performed.

Hereinafter, the film-like adhesive will be described. As an example of the film-like adhesive, an adhesive containing an epoxy resin, an epoxy resin curing agent, and a (meth)acrylic copolymer having an epoxy group will be described. The film-like adhesive containing these components is excellent in adhesiveness between a chip and a substrate and between a chip and a chip. Furthermore, electrode embeddability, wire embeddability, and the like can also be imparted to this film-like adhesive, and adhesiveness at a low temperature in the die bonding step can also be imparted thereto.

Examples of the epoxy resin include a bisphenol A type epoxy resin, a bisphenol F type epoxy resin, a bisphenol S type epoxy resin, a phenol novolak type epoxy resin, a cresol novolak type epoxy resin, a bisphenol A novolak type epoxy resin, a bisphenol F novolak type epoxy resin, a dicyclopentadiene skeleton-containing epoxy resin, a stilbene type epoxy resin, a triazine skeleton-containing epoxy resin, a fluorene skeleton-containing epoxy resin, a triphenol phenol methane type epoxy resin, a biphenyl type epoxy resin, a xylylene type epoxy resin, a biphenyl aralkyl type epoxy resin, a naphthalene type epoxy resin, and a diglycidyl ether compound of a polyfunctional phenol or a polycyclic aromatic compound such as anthracene. These may be used singly or in combination of two or more kinds thereof.

The epoxy resin curing agent may be, for example, a phenolic resin. The phenolic resin can be used without particular limitation as long as it has a phenolic hydroxyl group in the molecule. Examples of the phenolic resin include novolak type phenolic resins obtained by condensation or co-condensation of phenols such as phenol, cresol, resorcin, catechol, bisphenol A, bisphenol F, phenylphenol, and aminophenol and/or naphthols such as α-naphthol, β-naphthol, and dihydroxynaphthalene with a compound having an aldehyde group such as formaldehyde in the presence of an acidic catalyst; and phenol aralkyl resins and naphthol aralkyl resins synthesized from phenols such as allylated bisphenol A, allylated bisphenol F, allylated naphthalene diol, phenol novolak, and phenol and/or naphthols with dimethoxyparaxylene or bis(methoxymethyl)biphenyl. These may be used singly or in combination of two or more kinds thereof.

The (meth)acrylic copolymer having an epoxy group may be a copolymer in which the amount of glycidyl (meth)acrylate as a raw material is adjusted to be 0.5 to 6% by mass with respect to the obtained copolymer. When this amount is 0.5% by mass or more, there is a tendency that a high adhesion force is easily obtained, and when this amount is 6% by mass or less, there is a tendency that gelation can be suppressed. The remaining part of glycidyl (meth)acrylate may be alkyl (meth)acrylate having an alkyl group having 1 to 8 carbon atoms such as methyl (meth)acrylate, and a mixture of styrene, acrylonitrile, and the like. The alkyl (meth)acrylate may contain ethyl (meth)acrylate and/or butyl (meth)acrylate. The mixing ratio of each component can be adjusted in consideration of Tg (glass transition temperature) of the (meth)acrylic copolymer having an epoxy group thus obtained. When Tg is −10° C. or higher, the tackiness of the adhesive film in the B-stage state tends to be satisfactory, and handling property tends to be excellent. The upper limit value of Tg of the (meth)acrylic copolymer having an epoxy group may be, for example, 30° C.

The weight average molecular weight of the (meth)acrylic copolymer having an epoxy group may be 100000 or more, 300000 to 3000000, or 500000 to 2000000. When the weight average molecular weight is 3000000 or less, there is a tendency that a decrease in fillability between a semiconductor chip and a support substrate can be suppressed. The weight average molecular weight is a value in terms of polystyrene using a calibration curve of standard polystyrene by gel permeation chromatography (GPC).

The curing accelerator may further contain, as necessary, curing accelerators such as tertiary amine, imidazoles, and quaternary ammonium salts. Examples of the curing accelerator include 2-methylimidazole, 2-ethyl-4-methylimidazole, 1-cyanoethyl-2-phenylimidazole, and 1-cyanoethyl-2-phenylimidazolium trimellitate. These may be used singly or in combination of two or more kinds thereof.

The film-like adhesive may further contain, as necessary, an inorganic filler. Examples of the inorganic filler include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, crystalline silica, and amorphous silica. These may be used singly or in combination of two or more kinds thereof.

The above-described components are dissolved or dispersed in a solvent to prepare a varnish, and the varnish is applied onto the support and heated so as to remove the solvent. Thereby, the film-like adhesive can be formed. As the support, plastic films such as polytetrafluoroethylene, polyethylene terephthalate, polyethylene, polypropylene, polymethylpentene, and polyimide can be used, and these supports can also be used after the surfaces thereof are release-treated.

The solvent is not particularly limited, and in consideration of volatility or the like at the time of film formation, it is preferable to use solvents having a relatively low boiling point such as methanol, ethanol, 2-methoxyethanol, 2-butoxyethanol, methyl ethyl ketone, acetone, methyl isobutyl ketone, 2-ethoxyethanol, toluene, and xylene. Furthermore, for improving coating film properties, solvents having a relatively high boiling point such as dimethylacetamide, dimethylformamide, N-methylpyrrolidone, and cyclohexanone can also be added.

In the production of a varnish containing an inorganic filler, in consideration of the dispersibility of the inorganic filler, it is preferable to use a raikai mixer, a triple roll, a ball mill, a bead mill, or the like and these can also be used in combination. Furthermore, by mixing an inorganic filler and a low-molecular-weight material in advance and then blending a high-molecular-weight material therewith, the mixing time can also be shortened. Furthermore, after preparing a varnish, air bubbles in the varnish can also be removed by vacuum deaeration or the like.

As the method of applying the varnish to the support, known methods can be used, and examples thereof include a knife coating method, a roll coating method, a spray coating method, a gravure coating method, a bar coating method, and a curtain coating method. Note that, the bonding adhesive layer 5 formed on the support may be attached to the adhesive layer 2 by hot roll lamination, and the bonding adhesive layer 5 may be formed on the surface of the adhesive layer 2 by printing.

The thickness of the film-like adhesive (the bonding adhesive layer 5) is not particularly limited, and is preferably 3 to 150 μm, more preferably 4 to 140 μm, and further preferably 5 to 135 μm. When the thickness of the film-like adhesive (the thickness of the sample S) is 3 μm or less, the breaking strength P is too small, and thus there is a tendency that the stability of data is insufficient. When the thickness thereof exceeds 150 μm, the installation of the sample S is difficult, and thus there is a tendency that the stability of data is insufficient. From the viewpoint of the stability and the handling property of data, the thickness of the film-like adhesive is particularly preferably about 3 to 135 μm.

According to the studies of the present inventors, the breaking work W (N·mm) can be adjusted, for example, by increasing or decreasing the content of the (meth)acrylic copolymer. The breaking strength P (N) can be adjusted, for example, by increasing or decreasing the content of the inorganic filler. The breaking elongation L (mm) can be adjusted, for example, by increasing or decreasing the content of the (meth)acrylic copolymer.

The base layer 1 and the adhesive layer 2 provided in the film 10 are also referred to as a dicing film. The base layer 1 is formed from, for example, plastic films such as a polytetrafluoroethylene film, a polyethylene terephthalate film, a polyethylene film, a polypropylene film, a polymethylpentene film, and a polyimide film. The surface of the base layer 1 may be subjected to a surface treatment such as a primer application, an MV treatment, a corona discharge treatment, a polishing treatment, or an etching treatment, as necessary, The thickness of the base layer 1 is, for example, 60 to 150 μm and preferably 70 to 130 μm. As the base layer 1, those which are not broken at the time of cooling expansion are applied.

The adhesive layer 2 may be, for example, a pressure-sensitive type or ultraviolet curable type. It is preferable that the adhesive layer 2 has such an adhesive force that adhesive piece-attached chips 8 are scattered at the time of cooling expansion, and has excellent peelability in the subsequent pickup step.

In the above-described embodiment, the dicing/die bonding integrated film 10 including the film-like adhesive as the bonding adhesive layer 5 has been described as an example, but the film-like adhesive may be used alone.

### EXAMPLES

Hereinafter, the present disclosure will be more specifically described by way of Examples; however, the present invention is not limited thereto.

<Evaluation of Ease of Splitting of Film-Like Adhesive>

Adhesive pieces (width 5 mm× length 100 mm) were cut from film-like adhesives according to Examples and Comparative Examples described below. The adhesive pieces were fixed by a pair of jigs (thick paper) and protruding portions of the adhesive pieces from the jigs were removed. Thereby, evaluation target samples (width 5 mm×length 23 mm) were obtained. A break test was performed in a thermostat bath (manufactured by AETEC Co., Ltd., TLF-R3-F-W-PL-S) set to a predetermined temperature condition. That is, the break test was performed using an autograph (manufactured by A&D Company, Limited, AZT-CA01, load cell 50 N) under the conditions of a compression mode, a speed of 10 mm/min, and a pushing distance of 5 mm, and the breaking work W, the breaking strength P, and the breaking elongation L when the film-like adhesive was broken were determined. The breaking factor in and the breaking resistance R were calculated by the above Equation (1) and Equation (2). Note that, the break test was performed eight times or more for each Example and each Comparative Example. Values described in Tables 1 and 2 are average values obtained as the results of plural times of the break test.

For checking that the above-described evaluation of ease of splitting matches the ease of splitting in cooling expansion, dicing/die-bonding integrated films including film-like adhesives according to Examples and Comparative Examples described below as the bonding adhesive layer were produced respectively, and the ease of splitting of the bonding adhesive layers were evaluated under the following conditions.
Thickness of silicon wafer: 30 μm
Size of chip to be singulated by stealth dicing: Length 10 mm×width 10 mm
Temperature of cooling expansion: Temperature equal to temperature of thermostat bath of break test in Examples and Comparative Examples
Thrusting by ring for expansion: 10 mm
Evaluation criteria: A silicon wafer after being thrust by the ring for expansion was irradiated with light. A case where light passes between adjacent adhesive piece-attached chips (the silicon wafer and the bonding adhesive layer are divided) was regarded as “A”, and a case where there is a region through which light does not pass (the silicon wafer and the bonding adhesive layer are not divided) was regarded as “B”.

<Production of Film-Like Adhesive>

### Example 1

A composition containing the following components was prepared.

### [Epoxy Resin]

o-Cresol novolak type epoxy resin (manufactured by Nippon Steel & Sumikin Chemical Co., Ltd., trade name: YDCN-700-10, epoxy equivalent 210 g/eq, softening point 80° C.): 22 parts by mass
Bisphenol F type epoxy resin (manufactured by DIC Corporation, trade name EXA-830CRP, epoxy equivalent 160 g/eq, liquid state at 25° C.): 20 parts by mass

### [Epoxy Resin Curing Agent]

Phenolic resin (manufactured by Mitsui Chemicals, Inc., trade name: XLC-LL, softening point: 75° C.): 32 parts by mass

### [Silane Coupling Agent]

3-Mercaptopropyltrimethoxysilane (manufactured by Momentive Performance Materials Japan LLC, trade name: A-189): 0.1 parts by mass
3-Ureidopropyltriethoxysilane (manufactured by Momentive Performance Materials Japan LLC, trade name: A-1160): 0.3 parts by mass

### [Filler]

Silica (manufactured by Admatechs Company Limited): 41 parts by mass

### [Solvent]

Cyclohexanone

The following components were further added to the above-described composition and mixed and then subjected to vacuum deaeration, thereby preparing a varnish for a film-like adhesive.
Acrylic rubber (manufactured by Nagase ChemteX Corporation, trade name: HTR-860P-3, weight average molecular weight 800000, butyl acrylate/ethyl acrylate/acrylonitrile/glycidyl methacrylate (mass ratio)=38.6/28.7/29.7/3.0, glycidyl group-containing repeating unit: 3.0% by mass): 23 parts by mass
Curing accelerator (1-cyanoethyl-2-phenylimidazole, manufactured by SHIKOKU CHEMICALS CORPORATION, trade name: 2PZ-CN): 0.1 parts by mass

The varnish was applied onto the surface of a release-treated polyethylene terephthalate film (thickness 38 μm) and then heated so as to remove the solvent. Thereby, a film-like adhesive in the B-stage state (thickness 60 μm) was obtained. The ease of splitting of this film-like adhesive was evaluated at a temperature of 0° C. The result is shown in Table 1.

### Example 2

A film-like adhesive was obtained in the same manner as in Example 1, except that the thickness was set to 50 μm instead of 60 μm. The ease of splitting of this film-like adhesive was evaluated at a temperature of 0° C. The result is shown in Table 1.

### Example 3

A composition containing the following components was prepared.

### [Epoxy Resin]

o-Cresol novolak type epoxy resin (manufactured by Nippon Steel & Sumikin Chemical Co., Ltd., trade name: YDCN-700-10, epoxy equivalent 210 g/eq, softening point 80° C.): 6 parts by mass

### [Epoxy Resin Curing Agent]

Phenolic resin (manufactured by AIR WATER INC., trade name: SK Resin-HE100-C): 3 parts by mass
Phenolic resin (manufactured by Nippon Kayaku Co., Ltd., trade name: GPH-103): 3 parts by mass

### [Silane Coupling Agent]

3-Mercaptopropyltrimethoxysilane (manufactured by Momentive Performance Materials Japan LLC, trade name: A-189): 0.5 parts by mass
Phenylaminopropyltrimethoxysilane (manufactured by Momentive Performance Materials Japan LLC, trade name: Y9669): 1 part by mass

### [Filler]

Silica (manufactured by Admatechs Company Limited): 30 parts by mass

### [ Solvent]

Cyclohexanone

The following components were further added to the above-described composition and mixed and then subjected to vacuum deaeration, thereby preparing a varnish for a film-like adhesive.
Acrylic rubber (manufactured by Nagase ChemteX Corporation, trade name: HTR-860P-3, weight average molecular weight 800000, butyl acrylate/ethyl acrylate/acrylonitrile/glycidyl methacrylate (mass ratio)=38.6/28.7/29.7/3.0, glycidyl group-containing repeating unit: 3.0% by mass): 57 parts by mass
Curing accelerator (1-cyanoethyl-2-phenylimidazole, manufactured by SHIKOKU CHEMICALS CORPORATION, trade name: 2PZ-CN): 0.01 parts by mass

The above-described varnish was applied onto the surface of a release-treated polyethylene terephthalate film (thickness 38 μm) and then heated so as to remove the solvent. Thereby, a film-like adhesive in the B-stage state (thickness 7 μm) was obtained. The ease of splitting of this film-like adhesive was evaluated at a temperature of −5° C. The result is shown in Table 1.

### Example 4

A film-like adhesive was obtained in the same manner as in Example 3, except that the thickness was set to 20 μm instead of 7 μm. The ease of splitting of this film-like adhesive was evaluated at a temperature of −10° C. The result is shown in Table 1.

### Comparative Example 1

A composition containing the following components was prepared.

### [Epoxy Resin]

o-Cresol novolak type epoxy resin (manufactured by Nippon Steel & Sumikin Chemical Co., Ltd., trade name: YDCN-700-10, epoxy equivalent 210 g/eq, softening point 80° C.): 7 parts by mass

### [Epoxy Resin Curing Agent]

Phenolic resin (manufactured by Mitsui Chemicals, Inc., trade name: XLC-LL, softening point: 75° C.): 3 parts by mass

### [Epoxy Resin Curing Agent]

Phenolic resin (manufactured by Nippon Kayaku Co., Ltd., trade name: GPH-103): 4 parts by mass

### [Silane Coupling Agent]

3-Mercaptopropyltrimethoxysilane (manufactured by Momentive Performance Materials Japan LLC, trade name: A-189): 0.4 parts by mass
Phenylaminopropyltrimethoxysilane (manufactured by Momentive Performance Materials Japan LLC, trade name: Y9669): 1 part by mass

### [Filler]

Silica (manufactured by Admatechs Company Limited): 16 parts by mass

### [ Solvent]

Cyclohexanone

The following components were further added to the above-described composition and mixed and then subjected to vacuum deaeration, thereby preparing a varnish for a film-like adhesive.
Acrylic rubber (manufactured by Nagase ChemteX Corporation, trade name: HTR-860P-3, weight average molecular weight 800000, butyl acrylate/ethyl acrylate/acrylonitrile/glycidyl methacrylate (mass ratio)=38.6/28.7/29.7/3.0, glycidyl group-containing repeating unit: 3.0% by mass): 68 parts by mass
Curing accelerator (1-cyanoethyl-2-phenylimidazole, manufactured by SHIKOKU CHEMICALS CORPORATION, trade name: 2PZ-CN): 0.01 parts by mass

The above-described varnish was applied onto the surface of a release-treated polyethylene terephthalate film (thickness 38 μm) and then heated so as to remove the solvent. Thereby, a film-like adhesive in the B-stage state (thickness 7 μm) was obtained. The ease of splitting of this film-like adhesive was evaluated at a temperature of −5° C. The result is shown in Table 2.

### Comparative Example 2

A composition containing the following components was prepared.

### [Epoxy Resin]

o-Cresol novolak type epoxy resin (manufactured by Nippon Steel & Sumikin Chemical Co., Ltd., trade name: YDCN-700-10, epoxy equivalent 210 g/eq, softening point 80° C.): 13 parts by mass

### [Epoxy Resin Curing Agent]

Phenolic resin (manufactured by Mitsui Chemicals, Inc., trade name: XLC-LL, softening point: 75° C.): 11 parts by mass

### [Silane Coupling Agent]

3-Mercaptopropyltrimethoxysilane (manufactured by Momentive Performance Materials Japan LLC, trade name: A-189): 0.4 parts by mass
3-Ureidopropyltriethoxysilane (manufactured by Momentive Performance Materials Japan LLC, trade name: A-1160): 1 part by mass

### [Filler]

Silica (manufactured by NIPPON AEROSIL CO., LTD.): 8 parts by mass

### [ Solvent]

Cyclohexanone

The following components were further added to the above-described composition and mixed and then subjected to vacuum deaeration, thereby preparing a varnish for a film-like adhesive.
Acrylic rubber (manufactured by Nagase ChemteX Corporation, trade name: HTR-860P-3, weight average molecular weight 800000, butyl acrylate/ethyl acrylate/acrylonitrile/glycidyl methacrylate (mass ratio)=38.6/28.7/29.7/3.0, glycidyl group-containing repeating unit: 3.0% by mass): 66 parts by mass
Curing accelerator (1-cyanoethyl-2-phenylimidazole, manufactured by SHIKOKU CHEMICALS CORPORATION, trade name: 2PZ-CN): 0.03 parts by mass

The above-described varnish was applied onto the surface of a release-treated polyethylene terephthalate film (thickness 38 μm) and then heated so as to remove the solvent. Thereby, a film-like adhesive in the B-stage state (thickness 10 μm) was obtained. The ease of splitting of this film-like adhesive was evaluated at a temperature of 0° C. The result is shown in Table 2.

### Comparative Example 3

The ease of splitting of the film-like adhesive (thickness 7 μm) obtained in the same manner as in Comparative Example 1 was evaluated at a temperature of −10° C. The result is shown in Table 2.

### Comparative Example 4

A film-like adhesive was obtained in the same manner as in Comparative Example 1, except that the thickness was set to 20 μm instead of 7 μm. The ease of splitting of this film-like adhesive was evaluated at a temperature of −10° C. The result is shown in Table 2.

TABLE 1

| | | Ex. 1 | Ex. 2 | Ex. 3 | Ex. 4 |
|---|---|---|---|---|---|
| Break | Thickness of sample (μm) | 60 | 50 | 7 | 20 |
| test | Temperature (° C.) | 0 | 0 | −5 | −10 |
| | Breaking work W (N · mm) | 0.13 | 0.29 | 0.52 | 1.58 |
| | Breaking factor m (—) | 30 | 29 | 51 | 52 |
| | Breaking resistance R | 2 | 5 | 33 | 34 |
| | (N/mm²) | | | | |

| | | | | |
|---|---|---|---|---|
| Evaluation of ease of splitting | A | A | A | A |
| by cooling expansion | | | | |

TABLE 2

| | | Comp. | Comp. | Comp. | Comp. |
|---|---|---|---|---|---|
| | | Ex. 1 | Ex. 2 | Ex. 3 | Ex. 4 |
| Break | Thickness of sample (μm) | 7 | 10 | 7 | 20 |
| test | Temperature (° C.) | −5 | 0 | −10 | −10 |
| | Breaking work W (N · mm) | 2.45 | 2.70 | 1.57 | 2.92 |
| | Breaking factor m (—) | 122 | 128 | 105 | 74 |
| | Breaking resistance R | 56 | 43 | 46 | 42 |
| | (N/mm²) | | | | |

| | | | | |
|---|---|---|---|---|
| Evaluation of ease of splitting | B | B | B | B |
| by cooling expansion | | | | |

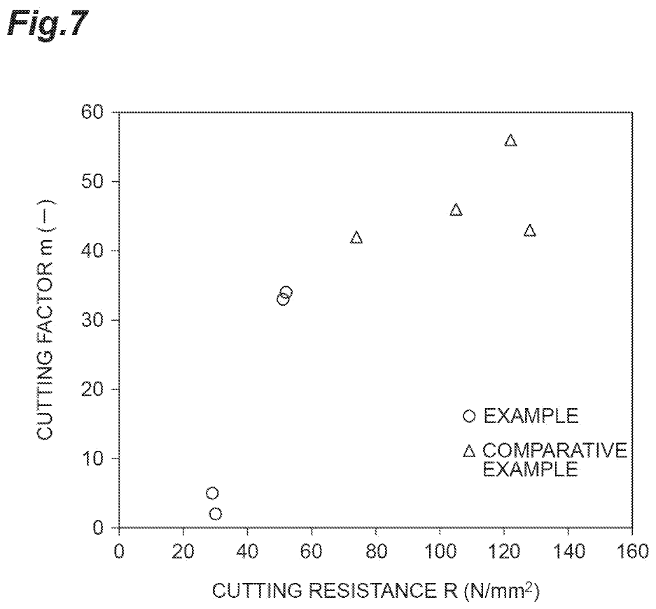

As shown in Table 1, in Examples 1 to 4, the breaking factor in was 70 or less, the breaking resistance R was 40 N/mm² or less, and the evaluation of ease of splitting by cooling expansion was “A”. On the other hand, as shown in Table 2, in Comparative Examples 1 to 4, the breaking factor in was more than 70, the breaking resistance R was more than 40 N/mm², and the evaluation of ease of splitting by cooling expansion was “B”. The evaluation of ease of splitting using the results of the break test performed in Examples and Comparative Examples can be said to match the results of the evaluation of ease of break by cooling expansion. FIG. 7 is a graph on which results of Examples and Comparative Examples are plotted.

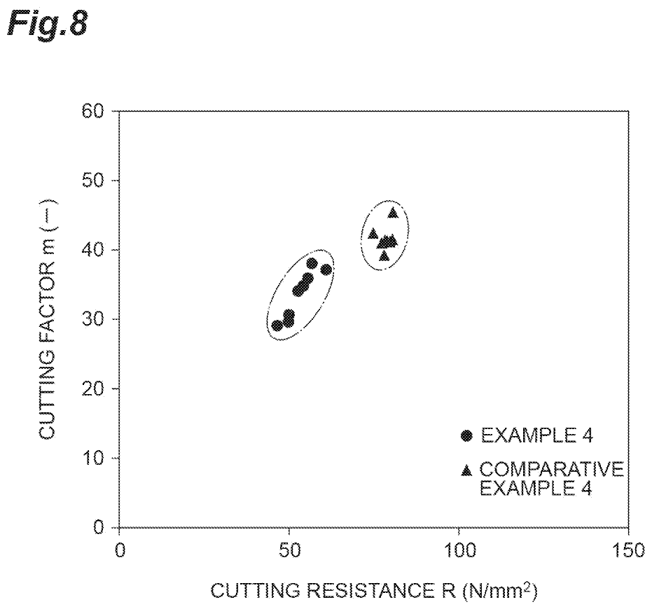

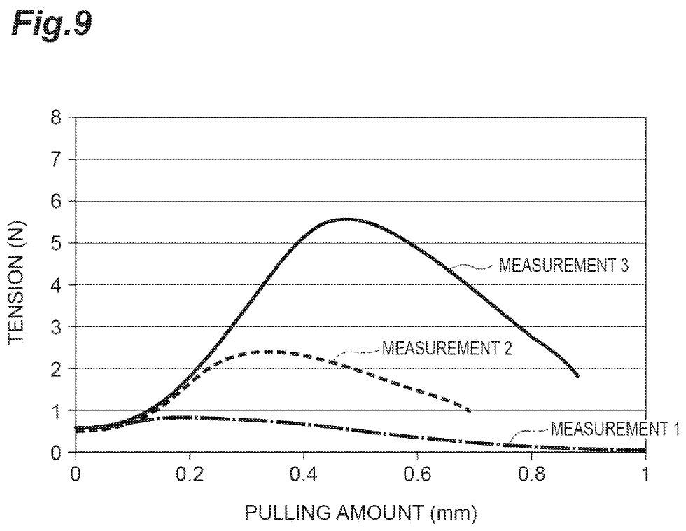

FIG. 8 is a graph on which results of a break test performed eight times in each of Example 4 and Comparative Example 4 are plotted. From this graph, the reproducibility of the above-described break test can be said to be sufficiently high. On the other hand, FIG. 9 is a graph showing results of a tensile test performed three times for a sample of a film-like adhesive (width 10 mm× length 100 mm× thickness 60 μm) at a temperature of −15° C. As shown in FIG. 9, in a conventional low-temperature tensile test, a variation for each test is large, and it is difficult to evaluate the ease of splitting of the film-like adhesive from the results of this test.

### INDUSTRIAL APPLICABILITY

According to the present disclosure, there is provided a method by which the ease of splitting of a film-like adhesive under low-temperature conditions in which cooling expansion is performed can be evaluated with ease and excellent reproducibility. Furthermore, according to the present disclosure, there are also provided a film-like adhesive that is satisfactorily split by cooling expansion, a dicing/die-bonding integrated film including the film-like adhesive as a bonding adhesive layer, a method for manufacturing the dicing/die-bonding integrated film, and a semiconductor device.

### REFERENCE SIGNS LIST

1: base layer, 2: adhesive layer, 5: bonding adhesive layer (film-like adhesive), 8: adhesive piece-attached chip, 10: dicing/die-bonding integrated film, 12: sample fixing jig, 12a: opening, 15: push jig, S: sample, Wa: semiconductor wafer.

1. A method for evaluating an ease of splitting of a film-like adhesive under low-temperature conditions in which cooling expansion is performed, the method comprising:
preparing a sample having a cross-sectional area A (mm²) from the film-like adhesive;
determining a breaking work W (N·mm), a breaking strength P (N), and a breaking elongation L (mm) of the sample by a break test under low-temperature conditions in a range of −15° C. to 0° C.;
determining a breaking factor m of the sample expressed by:
m=W/[1000×(P×L)];
determining a breaking resistance R (N/mm²) of the sample expressed by:
R=P/A; and
evaluating the ease of splitting based on the determined breaking factor m and the determined breaking resistance R.

2. A method for manufacturing a dicing/die-bonding integrated film including a base layer, an adhesive layer having a first surface facing the base layer and a second surface opposite to the first surface, and a bonding adhesive layer provided on the second surface of the adhesive layer, the method comprising:
preparing a dicing film including the base layer and the adhesive layer;
selecting a film-like adhesive having a non-zero breaking factor m of 70 or less and a non-zero breaking resistance R of 40 N/mm² or less, for evaluating the ease of splitting according to claim 1 that is performed for the sample in which:
sample width equals 5 mm,
sample length equals 23 mm, and
a relative speed between a push jig and the sample equals 10 mm/min; and forming the bonding adhesive layer from the film-like adhesive on a surface of the dicing film facing the adhesive layer to obtain the dicing/die-bonding integrated film.

3. A film-like adhesive to be applied to a manufacturing process of a semiconductor device in which cooling expansion is performed,
the film-like adhesive having a non-zero breaking factor m of 70 or less and a non-zero breaking resistance R of 40 N/mm² or less for evaluating the ease of splitting according to claim 1 that is performed for the sample in which:
sample width equals 5 mm,
sample length equals 23 mm, and
a relative speed between a push jig and the sample equals 10 mm/min.

4. A dicing/die-bonding integrated film comprising:
a base layer;
an adhesive layer having a first surface facing the base layer and a second surface opposite to the first surface; and
a bonding adhesive layer provided on the second surface of the adhesive layer, wherein the bonding adhesive layer is formed from the film-like adhesive according to claim 3.

5. A semiconductor device comprising the film-like adhesive according to claim 3.
